(19) United States
(12) Patent Application Publication
(10) Pub. No.: US 2026/0271598 A1
(43) Pub. Date: Sep. 10, 2026

(54) DISPLAY SUBSTRATE AND DISPLAY DEVICE

(71) Applicants: Chengdu BOE Optoelectronics Technology Co., Ltd., Chengdu, Sichuan (CN); BOE TECHNOLOGY GROUP CO., LTD., Beijing (CN)

(72) Inventors: Shuo LI, Beijing (CN); Bin LIU, Beijing (CN)

(21) Appl. No.: 18/993,582

(22) PCT Filed: May 14, 2024
(86) PCT No.: PCT/CN2024/093132

§ 371 Date: Jan. 13, 2025

(30) Foreign Application Priority Data
Jun. 25, 2023 (CN) 202310752511.8

(51) Int. Cl. H10K 59/80; H10K 59/122

(52) U.S. Cl. CPC H10K 59/8792; H10K 59/122

(57) ABSTRACT

The present disclosure provides a display substrate and a display device. The display substrate includes a base substrate, a driving circuit layer, at least one planarization layer and a light-emitting device layer sequentially arranged on the base substrate. The display substrate further includes: a black pixel defining layer and a spacer on a side of the planarization layer away from the base substrate. In the first display region, an orthographic projection of the spacer on the base substrate does not overlap with orthographic projections of a pixel opening and a connection via on the base substrate. In the second display region, the orthographic projection of the spacer on the base substrate does not overlap with orthographic projections of the pixel opening and a first light-transmitting opening on the base substrate, and at least partially overlaps with the orthographic projection of the connection via on the base substrate.

### TECHNICAL FIELD

The present disclosure belongs to the field of display technology, and in particular, to a display substrate and a display device.

### BACKGROUND

An Organic Light-Emitting Diode (OLED) is a light-emitting device using an organic solid semiconductor as a light-emitting material, and has a wide application prospect due to its advantages such as a simple manufacture process, a low cost, a low power consumption, a high luminance, a wide operation temperature application range, and the like.

### SUMMARY

In order to at least solve one of the technical problems existing in the prior art, the present disclosure provides a display substrate and display device.

As a first aspect, an embodiment of the present disclosure provides a display substrate having a first display region and a second display region, wherein the display substrate includes a base substrate, a driving circuit layer, at least one planarization layer, and a light-emitting device layer sequentially arranged on the base substrate; the light-emitting device layer includes: a plurality of light-emitting devices each including a first electrode electrically connected to the driving circuit layer through a connection via penetrating through the at least one planarization layer; the display substrate further includes: a black pixel defining layer on a side of the at least one planarization layer away from the base substrate, and a spacer on a side of the black pixel defining layer away from the base substrate. In the first display region, the black pixel defining layer includes a plurality of pixel openings each exposing the first electrode; an orthographic projection of the spacer on the base substrate does not overlap with orthographic projections of the plurality of pixel openings and the connection via on the base substrate. In the second display region, the black pixel defining layer further includes a first light-transmitting opening between adjacent ones of a part of pixel openings; the orthographic projection of the spacer on the base substrate does not overlap with orthographic projections of the plurality of pixel openings and the first light-transmitting opening on the base substrate, and at least partially overlaps with the orthographic projection of the connection via on the base substrate.

Optionally, in the first display region, a part of the pixel openings have an irregular shape and have orientations arranged cyclically along a first direction, and at least two pixel openings with different orientations are disposed in each cycle; the orientation of the pixel opening is close to the spacer, and a difference between a distance from an edge of the orthographic projection of the spacer on the base substrate to an edge of an orthographic projection of one of two pixel openings adjacent to each other along the first direction on the base substrate and a distance from the edge of the orthographic projection of the spacer on the base substrate to an edge of an orthographic projection of the other of the two pixel openings on the base substrate is smaller than a threshold value, and the orientation of the pixel opening is away from the spacer, and the difference between the distance from the edge of the orthographic projection of the spacer on the base substrate to the edge of the orthographic projection of the one of the two pixel openings adjacent to each other along the first direction on the base substrate and the distance from the edge of the orthographic projection of the spacer on the base substrate to the edge of the orthographic projection of the other of the two pixel openings on the base substrate is greater than the threshold value.

Optionally, the orientation of the pixel opening is close to the spacer, and the distance from the edge of the orthographic projection of the spacer on the base substrate to the edge of the orthographic projection of the one of the two pixel openings adjacent to each other along the first direction on the base substrate and the distance from the edge of the orthographic projection of the spacer on the base substrate to the edge of the orthographic projection of the other of the two pixel openings on the base substrate are each in a range of 13 μm±0.5 μm, and the orientation of the pixel openings is away from the spacer, the distance from the edge of the orthographic projection of the spacer on the base substrate to the edge of the orthographic projection of the one of the two pixel openings adjacent to each other along the first direction on the base substrate is in a range of 13 μm±0.5 μm, and the distance from the edge of the orthographic projection of the spacer on the base substrate to the edge of the orthographic projection of the other of the two pixel openings on the base substrate is in a range of 16 μm±0.5 μm.

Optionally, a difference between a distance from an edge of the orthographic projection of the spacer on the base substrate to an edge of an orthographic projection of one of two pixel openings adjacent to each other along a second direction on the base substrate and a distance from the edge of the orthographic projection of the spacer on the base substrate to an edge of an orthographic projection of the other of the two pixel openings on the base substrate is smaller than a threshold value, and the second direction intersects with the first direction.

Optionally, the distance from the edge of the orthographic projection of the spacer on the base substrate to the edge of the orthographic projection of the one of the two pixel openings adjacent to each other along the second direction on the base substrate and the distance from the edge of the orthographic projection of the spacer on the base substrate to the edge of the orthographic projection of the other of the pixel openings on the base substrate are each in a range of 14 μm±0.5 μm.

Optionally, in the second display region, an orthographic projection of at least one spacer on the base substrate partially overlaps with an orthographic projection of at least one of two adjacent connection vias on the base substrate.

Optionally, the orthographic projection of the at least one spacer on the base substrate partially overlaps with orthographic projections of the two adjacent connection vias on the base substrate, respectively.

Optionally, a distance from an edge of the orthographic projection of the at least one spacer on the base substrate to an edge of an orthographic projection of one of the two adjacent connection vias on the base substrate is equal to a distance from an opposite edge of the orthographic projection of the spacer on the base substrate to an edge of an orthographic projection of the other of the two adjacent connection vias on the base substrate.

Optionally, the distance from the edge of the orthographic projection of the at least one spacer on the base substrate to the edge of the orthographic projection of the one of the two adjacent connection vias on the base substrate and the distance from the opposite edge of the orthographic projection of the spacer on the base substrate to the edge of the orthographic projection of the other of the two adjacent connection vias on the base substrate are each in a range from 0.2 μm to 0.5 μm.

Optionally, the spacer has a length in a range of 10 μm±0.5 μm along a first direction and a length in a range of 13 μm±0.5 μm along a second direction, with the second direction intersecting with the first direction.

Optionally, an arrangement density of the spacer is greater than or equal to 0.8%.

Optionally, the display substrate further includes an encapsulation layer and a black matrix layer sequentially arranged on a side of the light-emitting device layer away from the base substrate, wherein the black matrix layer includes a second light-transmitting opening, and an orthographic projection of the second light-transmitting opening on the base substrate at least partially overlaps with an orthographic projection of the corresponding pixel opening on the base substrate.

Optionally, an area of the orthographic projection of the second light-transmitting opening on the base substrate is larger than an area of the orthographic projection of the corresponding pixel opening on the base substrate.

Optionally, the orthographic projection of each pixel opening on the base substrate is within the orthographic projection of the corresponding second light-transmitting opening on the base substrate.

Optionally, a distance from an edge of the orthographic projection of the spacer on the base substrate to an edge of an orthographic projection of the black matrix layer on the base substrate is greater than or equal to 1.58 μm.

Optionally, the display substrate further includes a color filter layer including a plurality of color filters, wherein each of the plurality of color filters covers the second light-transmitting opening.

Optionally, each color filter has the same color as a color of a light-emitting device in the corresponding pixel opening.

Optionally, the black matrix layer further includes a third light-transmitting opening between adjacent ones of a part of the second light-transmitting openings; and an orthographic projection of the third light-transmitting opening on the base substrate at least partially overlaps with the orthographic projection of the first light-transmitting opening on the base substrate.

Optionally, an area of the orthographic projection of the third light-transmitting opening on the base substrate is larger than an area of the orthographic projection of the first light-transmitting opening on the base substrate.

Optionally, the orthographic projection of the first light-transmitting opening on the base substrate is within the orthographic projection of the third light-transmitting opening on the base substrate.

Optionally, the driving circuit layer includes a plurality of first hollow portions, and an orthographic projection of each first hollow portion on the base substrate at least partially overlaps with the orthographic projection of the corresponding connection via on the base substrate.

Optionally, the driving circuit layer further includes a flat portion between the adjacent first hollow portions, and an orthographic projection of the flat portion on the base substrate at least partially overlaps with the orthographic projection of the corresponding pixel opening on the base substrate.

Optionally, the driving circuit layer further includes a second hollow portion, and an orthographic projection of the second hollow portion on the base substrate at least partially overlaps with the orthographic projection of the corresponding pixel opening on the base substrate.

As a second aspect, an embodiment of the present disclosure provides a display device including the display substrate described above.

### BRIEF DESCRIPTION OF DRAWINGS

FIG. 1a to FIG. 1e are schematic diagrams showing structures of layers of a display substrate according to an embodiment of the present disclosure.

FIG. 2 is a schematic cross-sectional view showing a structure of the display substrate in FIG. 1e along a direction A-A′.

FIG. 3 is a schematic cross-sectional view showing a structure of the display substrate in FIG. 1e along a direction B-B′.

FIGS. 4a and 4b are schematic diagram showing a partial structure in a first display region of the display substrate in FIG. 1e.

FIG. 5 is a schematic diagram showing a partial structure in a second display region of the display substrate in FIG. 1e.

FIG. 6 is a schematic diagram showing a structure of a spacer of the display substrate in FIG. 1e.

FIG. 7a to FIG. 7e are schematic diagrams showing structures of layers of a display substrate according to another embodiment of the present disclosure.

### DETAIL DESCRIPTION OF EMBODIMENTS

In order to enable one of ordinary skill in the art to better understand the technical solutions of the present disclosure, the present disclosure will be described in further detail with reference to the accompanying drawings and the detailed description.

Unless defined otherwise, technical or scientific terms used herein shall have the ordinary meaning as understood by one of ordinary skill in the art to which the present disclosure belongs. The terms “first”, “second”, and the like used in the present disclosure are not intended to indicate any order, quantity, or importance, but rather are used for distinguishing one element from another. Further, the term “a”, “an”, “the”, or the like used herein does not denote a limitation of quantity, but rather denotes the presence of at least one element. The term of “comprising”, “including”, or the like, means that the element or item preceding the term contains the element or item listed after the term and its equivalent, but does not exclude other elements or items. The term “connected”, “coupled”, or the like is not limited to physical or mechanical connections, but may include electrical connections, whether direct or indirect connections. The terms “upper”, “lower”, “left”, “right”, and the like are used only for indicating relative positional relationships, and when the absolute position of an object being described is changed, the relative positional relationships may also be changed accordingly.

In order to prevent a display substrate from reflecting light, a conventional OLED display substrate generally has a polarizer attached to the display substrate to improve the comfort level of the display substrate under ambient light. However, the inventors of the present disclosure found that the transmittance of the polarizer is generally only about 40%, which results in a low light extraction rate and a high power consumption of the display substrate, and thus affects the display effect.

At present, in order to avoid the light shielding of the polarizer, a COE (Cover film On Encapsulation) technology is generally adopted, that is, the polarizer is replaced with a color filter (CF) layer, so as to improve the light extraction rate of the display substrate. Furthermore, this technology is conducive to the development of the display substrate towards high integration and lightweight.

In the COE technology, a black matrix layer is formed on the display substrate, the black matrix layer has a light-transmitting opening at a position corresponding to a light-emitting device in a pixel opening, allowing the light emitted by the light-emitting device to pass through. The above-mentioned color filter layer is formed in the light-transmitting opening. At this time, the black matrix layer may absorb light, thereby shielding a portion of the metal in the display substrate and reducing the light reflectivity of the display substrate. The color filter layer may filter light to form light in corresponding colors, further improving the utilization rate of light.

Meanwhile, a photosensitive element, such as an image sensor, a light sensor and the like for realizing functions such as fingerprint identification, display brightness adjustment and the like, is generally provided in the display substrate. In this case, the light transmittance of the display substrate needs to increased. A black pixel defining layer in the display substrate is generally perforated to form the light-transmitting opening, so that light can be transmitted through the light-transmitting opening of the black pixel defining layer, so as to sense light and realize the functions such as the fingerprint identification, the display brightness adjustment and the like.

However, a spacer in the display substrate is generally formed on the black pixel defining layer. Since the black pixel defining layer is perforated at a position at which the spacer is originally supported, the spacer cannot be placed at the position, so that the structure of the display substrate at the position easily collapse, and thus there is a difference among display pictures in different regions in the display substrate, whereby affecting the display effect and deteriorating the user's experience.

In order to solve at least one of the above technical problems, embodiments of the present disclosure provide a display substrate and a display device. The display substrate and the display device provided by the embodiments of the present disclosure will be described in further detail with reference to the accompanying drawings and the detailed description.

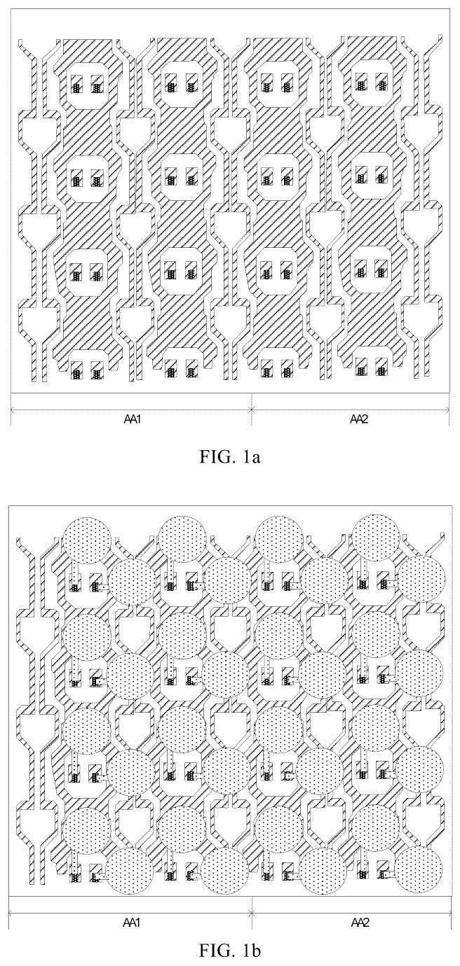

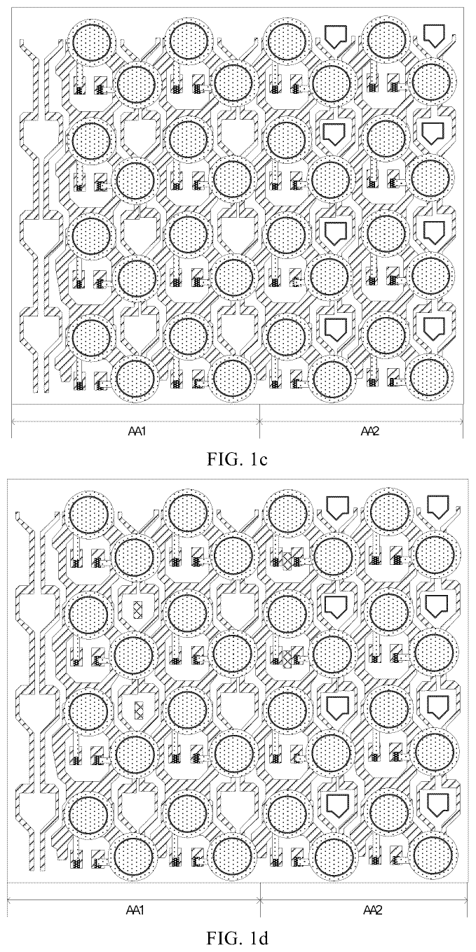

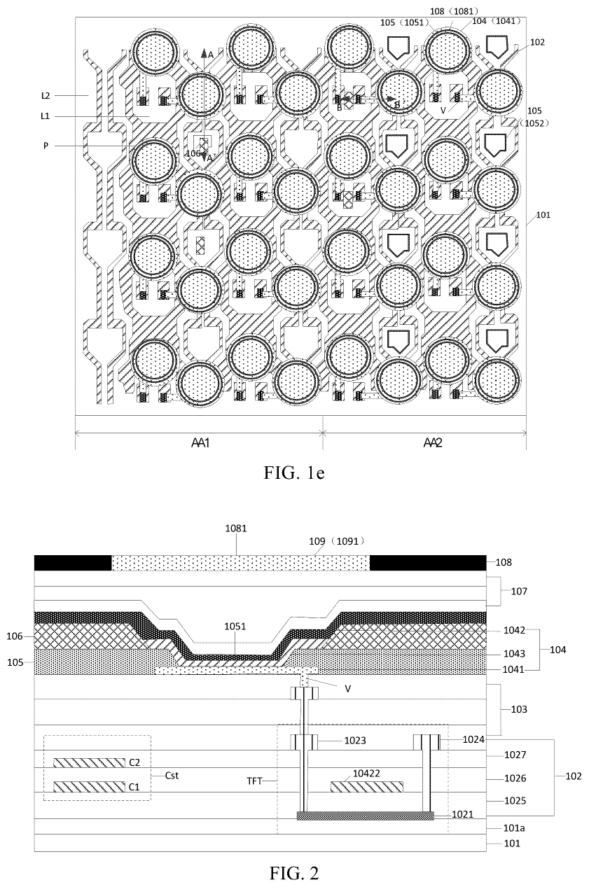

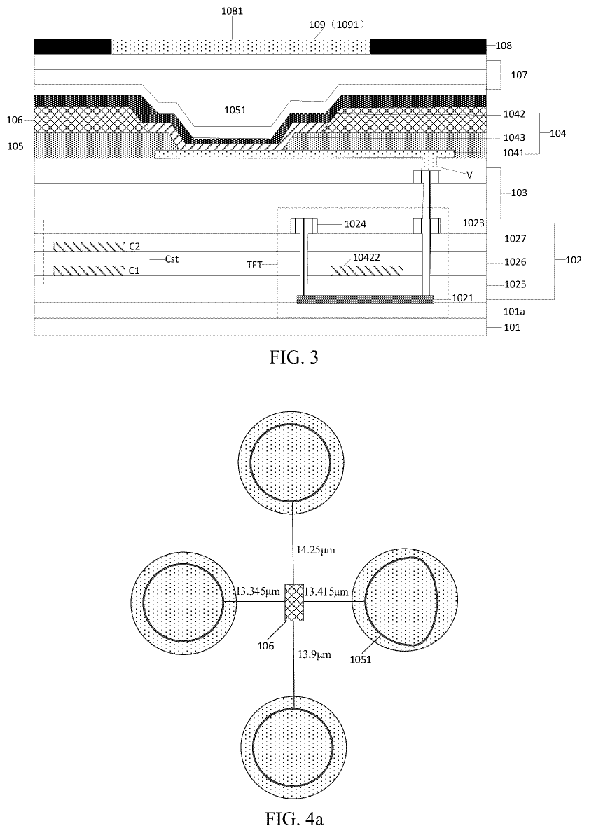

In a first aspect, an embodiment of the present disclosure provides a display substrate. FIG. 1a to FIG. 1e are schematic diagrams showing structures of film layers of a display substrate according to an embodiment of the present disclosure. FIG. 2 is a schematic cross-sectional diagram showing a structure of the display substrate in FIG. 1e along a direction A-A′. FIG. 3 is a schematic cross-sectional diagram showing a structure of the display substrate in FIG. 1e along a direction B-B′. Referring to FIG. 1a to FIG. 3, the display substrate includes a first display region AA1 and a second display region AA2. The display substrate includes: a base substrate 101, and a driving circuit layer 102, at least one planarization layer 103 and a light-emitting device layer 104 that are sequentially arranged on the base substrate 101. The light-emitting device layer 104 includes a plurality of light-emitting devices. Each of the light-emitting devices includes: a first electrode 1041 electrically connected to the driving circuit layer 102 through a connection via V penetrating through the at least one planarization layer 103. The display substrate further includes: a black pixel defining layer 105 on a side of the planarization layer 103 away from the base substrate 101 and a spacer 106 on a side of the black pixel defining layer 105 away from the base substrate 101. In the first display region AA1, the black pixel defining layer 105 has a plurality of pixel openings 1051 exposing the first electrodes 1041. An orthographic projection of the spacer 106 on the base substrate 101 does not overlap with orthographic projections of the pixel openings 1051 and the connection via V on the base substrate 101. In the second display region AA2, the black pixel defining layer 105 further has a first light-transmitting opening 1052 between adjacent ones of a part of the pixel openings 1051. The orthographic projection of the spacer 106 on the base substrate 101 does not overlap the orthographic projections of the pixel openings 1051 and the first light-transmitting opening 1052 on the base substrate 101, and at least partially overlaps the orthographic projection of the connection via V on the base substrate 101.

The first display region AA1 of the display substrate may be a normal display region in which structures such as a pixel driving circuit and a light-emitting device are disposed to realize the display function, and the second display region AA2 may be a sensing display region in which not only the above structures such as the pixel driving circuit and the light-emitting device for display are disposed but also a light sensing element such as an image sensor and a light sensor are disposed to realize the functions such as the fingerprint identification and the display brightness adjustment. A plurality of second display regions AA2 may be disposed on one side or both sides of the first display region AA1 or surrounded by the first display region AA1, and each of the plurality of second display regions AA2 may have a circular shape, a rectangular shape, or an irregular shape. It should be understood that in the embodiment of the present disclosure, specific arrangement and shapes of the first display region AA1 and the second display region AA2 are not limited and may be set as actual needed.

The base substrate 101 may be made of a rigid material such as glass, thereby improving the carrying capacity of the base substrate 101 for other film layers thereon. Alternatively, the base substrate 101 may be made of a flexible material such as Polyimide (PI), thereby improving the overall bending and stretching resistance of the display substrate, and preventing the base substrate 101 from being broken due to the stress generated during the bending, stretching, and twisting processes, and therefore avoiding defects such as open circuits. In practical applications, the material of the base substrate 101 can be selected reasonably according to actual needs to ensure that the display substrate has good performance.

It is understood that film layers such as a buffer layer 101a may further be disposed on the base substrate 101. The buffer layer 101a may be made of at least one of silicon nitride (SiN) and silicon oxide (SiO₂), and may be formed as a single-layer structure made of a single material, or may be formed as a multi-layer structure made of a plurality of different materials in which a film layer in contact with an active layer of a transistor is a silicon oxide (SiO₂) layer, so as to prevent gases such as water and oxygen from invading into other film layers above the base substrate 101 from one side of the base substrate 101 to damage the display substrate. For example, the buffer layer 101a may specifically be a stacked structure including layers of silicon nitride (SiN) and silicon oxide (SiO₂), wherein the layer of silicon nitride (SiN) has a thickness from 300 Å to 2000 Å and the layer of silicon oxide (SiO₂) has a thickness from 1000 Å to 5000 Å.

The driving circuit layer 102 includes: a plurality of pixel driving circuits. Each pixel driving circuit includes at least one thin film transistor TFT and a storage capacitor Cst. The thin film transistor TFT includes: an active layer 1021, a gate electrode 1022, a source electrode 1023, a drain electrode 1024, etc., disposed on the base substrate 101. The storage capacitor Cst includes: a first electrode plate C1 and a second electrode plate C2 that are disposed on the base substrate 101, wherein the first electrode plate C1 is disposed in the same layer as the gate electrode 1022, and the second electrode plate C2 is disposed on a side of the first electrode plate C1 away from the base substrate 101.

It is understood that in the embodiments of the present disclosure, “in the same layer” refers to that two or more functional layers (or structural layers) are formed in the same layer in the hierarchical structure of the display substrate and are made of the same material, that is, in the manufacturing process, the two or more functional layers (or structural layers) may be formed by the same material layer, and the required patterns and structures may be formed in the same patterning process.

The display substrate may further include a first gate insulating layer 1025 disposed on the active layer 1021 on the base substrate 101, a second gate insulating layer 1026 disposed on the gate electrode 1022 and the first electrode plate C1, an interlayer insulating layer 1027 disposed on the second electrode plate C2, and the like.

The pixel driving circuit may include a structure of 2T1C (two thin film transistors TFT and one storage capacitor Cst), 6T1C (six thin film transistors TFT and one storage capacitor Cst), 7T1C (seven thin film transistors TFT and one storage capacitor Cts), and the like. The thin film transistor has a structure similar to or the same as the stacked structure of the thin film transistor TFT shown in FIG. 2. FIG. 2 only shows the thin film transistor TFT directly electrically connected to the light-emitting device. The thin film transistor TFT may be a driving thin film transistor, a light-emitting control thin film transistor, or the like.

At least one planarization layer 103 is further disposed on the driving circuit layer 102. For example, the source electrode 1023 of the thin film transistor TFT in the driving circuit layer 102 is electrically connected to the first electrode 1041 of the light-emitting device in the light-emitting device layer 104 through a connection via V penetrating through the planarization layer 103. In this case, only one planarization layer 1031 may be formed. For example, the display substrate further includes a connection electrode, the source electrode 1023 of the thin film transistor TFT in the driving circuit layer 102 is electrically connected to the first electrode 1041 of the light-emitting device in the light-emitting device layer 104 through the connection electrode, and two or three planarization layers 103 are required to planarize the film layers, and in this case, a plurality of planarization layers 103 may be formed. The planarization layer 103 may be made of organic materials such as acryl, resin, polyimide, or benzocyclobutene, which may be specifically selected according to actual needs. The planarization layer 103 may planarize the source electrode 1023, the drain electrode 1024, and the like to form a relatively flat surface for the adhesion of other layers thereon.

The light-emitting device layer 104 may include: a plurality of light-emitting devices. Each of the light-emitting devices includes: a first electrode 1041 and a second electrode 1042 which are oppositely arranged, and a light-emitting layer 1043 between the first electrode 1041 and the second electrode 1042. The first electrode 1041 and the second electrode 1042 have opposite polarities. Specifically, the first electrode 1041 may be an anode of the light-emitting device made of the metal material such as at least one of silver (Ag), aluminum (Al), and titanium (Ti). Specifically, the second electrode 1042 may be a cathode of the light-emitting device made of a transparent conductive material such as Indium Tin Oxide (ITO) or Indium Zinc Oxide (IZO), so as to improve the overall transparency of the display substrate. Each of the anode and the cathode may have a single-layer structure made of one of the above materials, or have a multi-layer structure made of multiple materials described above, which may be selected according to actual needs. The first electrode 1041 may be electrically connected to the source electrode 1023 of the thin film transistor TFT in the driving circuit layer 102 so that the driving circuit layer 102 provides a driving voltage for the light-emitting device, and the light-emitting layer 1043 of the light-emitting device may emit light under the driving of an electric field between the first electrode 1041 and the second electrode 1042, thereby implementing a multi-color display. It is understood that various other functional layers, for example, at least one of a Hole Injection Layer (HIL), a Hole Transport Layer (HTL), an Electron Transport Layer (ETL), and an Electron Injection Layer (EIL), may be further included in the light-emitting device and are provided with reference to the film structure in the related art, which will not be described in detail herein.

The black pixel defining layer 105 may be located on a side of the planarization layer 103 away from the base substrate 101, and may be made of an organic material such as acryl, resin, polyimide, or benzocyclobutene, and a carbon black additive is added to the black pixel defining layer 105 so that the black pixel defining layer 105 presents black. In the first display region AA1, the black pixel defining layer 105 has the plurality of pixel openings 1051, the first electrode 1041 of the light-emitting device is formed on the planarization layer 103 and covered by the black pixel defining layer 105, and the pixel opening 1051 may expose the first electrode 1041. With the definition of the black pixel defining layer 105, the functional film layers such as the light-emitting layer 1043 of the light-emitting device may be formed in the pixel opening 1051. The light-emitting layer 1043 is typically formed by an inkjet printing process, and the pixel opening 1051 of the black pixel defining layer 105 may provide a carrying space for the inkjet printing ink. In addition, in practical applications, the black pixel defining layer 105 may block light emitted from the light-emitting layer 1043, so as to avoid mutual crosstalk between light emitted from adjacent light-emitting devices. In the second display region AA2, in addition to the pixel openings 1051, the black pixel defining layer 105 further has the first light-transmitting opening 1052 disposed between adjacent ones of a part of the pixel openings 1051. The first light-transmitting opening 1052 can facilitate the transmission of light therethrough, thereby sensing light by using photosensitive components such as image sensors, light sensors, etc. and realizing functions such as the fingerprint recognition and the display brightness adjustment, and the like.

The spacer 106 may be located on a side of the black pixel defining layer 105 away from the base substrate 101 and may be used for supporting other film layers on the black pixel defining layer 105. The spacer 106 may be formed around the pixel opening 1051 of the black pixel defining layer 105, and block or dam materials of the functional film layers such as the light-emitting layer 1043 of the light-emitting device formed in the pixel opening 1051, so as to prevent the materials of the functional film layers such as the light-emitting layer 1043 from overflowing, and prevent the materials of the functional film layers such as the light-emitting layers 1043 in adjacent pixel openings 1051 from being contaminated with each other. The spacer 106 may be made of organic materials such as acryl, resin, polyimide, or benzocyclobutene.

Since no first light-transmitting opening 1052 is formed in the first display region AA1, the spacer 106 may be disposed between adjacent pixel openings 1051 in the black pixel defining layer 105 and not cover the region where the connection via V is located, thereby preventing the spacer 106 from collapsing in the region where the connection via V is located. Since the first light-transmitting opening 1052 is formed in the second display region AA2 so that the space for the spacer 106 is limited, the spacer may be disposed between adjacent pixel openings 1051 in the black pixel defining layer 105, and cover the region where the connection via V is located. Since an area of the second display region AA2 is far smaller than an area of the first display region AA1, with the same arrangement density, the number of the spacers 106 placed in the second display region AA2 is far smaller than the number of the spacers 106 placed in the first display region AA1. A part of the spacers 106 in the second display region AA2 may collapse, but which will not affect the supporting and blocking functions of the spacers 106.

In the display substrate provided by the embodiment of the present disclosure, in the first display region AA1, the spacer 106 may be disposed between the adjacent pixel openings 1051 in the black pixel defining layer 105 and do not cover the region where the connection via V is located, so as to prevent the spacer 106 from collapsing in the region where the connection via V is located. In the second display region AA2, the spacer 106 may be disposed between the adjacent pixel openings 1051 in the black pixel defining layer 105, and cover the region where the connection via V is located, so as to ensure that a certain number of spacers 106 are disposed in both of the first display region AA1 and the second display region AA2 of the display substrate, thereby avoiding a large difference between display images in the first display region AA1 and the second display region AA2 of the display substrate, improving the display effect of the display substrate, and improving the user's experience.

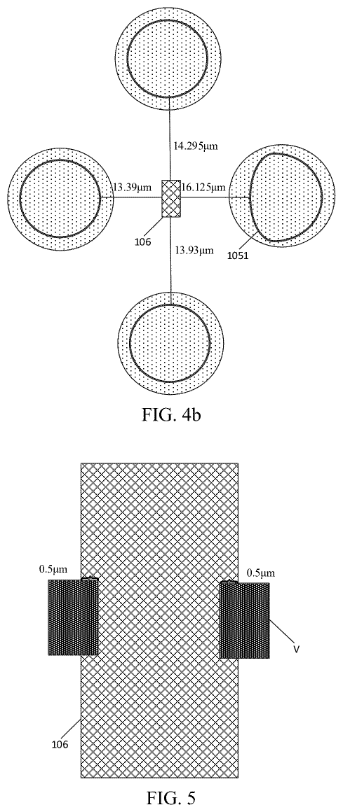

FIG. 4a and FIG. 4b are schematic diagrams showing a portion of the structure in the first display region of the display substrate shown in FIG. 1e. As shown in FIG. 4a and FIG. 4b, in the first display region AA1, a part of the pixel openings 1051 have an irregular shape and have orientations arranged cyclically along the first direction, and at least two pixel openings 1051 with different orientations are disposed in each cycle. When the orientation of the pixel opening 1051 is close to the spacer 106, a difference between a distance from an edge of an orthographic projection of the spacer 106 on the base substrate 101 to an edge of an orthographic projection of one of two pixel openings 1051 adjacent to each other along the first direction on the base substrate 101 and a distance from the edge of the orthographic projection of the spacer 106 on the base substrate 101 to an edge of an orthographic projection of the other of the two pixel openings 1051 on the base substrate 101 is smaller than a threshold value. When the orientation of the pixel opening 1051 is away from the spacer 106, the difference between the distance from the edge of the orthographic projection of the spacer 106 on the base substrate 101 to the edge of the orthographic projection of the one of the two pixel openings 1051 adjacent to each other along the first direction on the base substrate 101 and the distance from the edge of the orthographic projection of the spacer 106 on the base substrate 101 to the edge of the orthographic projection of the other of the two pixel openings 1051 on the base substrate 101 is greater than the threshold value.

In the embodiment of the present disclosure, each pixel opening 1051 has a circular shape or a circular-like shape as an example, where the circular shape is a regular shape and the circular-like shape is an irregular shape. The pixel openings 1051 may accommodate therein the light-emitting layers 1043 of the light-emitting devices in different colors. The pixel opening 1051 accommodating the red light-emitting layer may be referred to as a red pixel opening, the pixel opening 1051 accommodating the green light-emitting layer may be referred to as a green pixel opening, and the pixel opening accommodating the blue light-emitting layer may be referred to as a blue pixel opening. The green pixel opening and the blue pixel opening have a circular shape, and the red pixel opening has the irregular shape, that is, the circular-like shape. Since each of the green and blue pixel openings having the regular shape is uniform along all directions, the green and blue pixel openings have no difference in orientation.

The red pixel opening having the irregular shape is non-uniform along the first direction, which may be a row direction, that is, the red pixel opening has a certain relative offset along the first direction. For example, a straight line passing through a center of the red pixel opening and perpendicular to the first direction is taken as a center line, and a direction along which a portion of the red pixel opening having a larger area is located may be defined as an orientation of the red pixel opening. Specifically, on both sides of the center line, if an area of a portion of the red pixel opening on the left side is larger than an area of a portion of the red pixel opening on the right side, the red pixel opening faces the left side. If the spacer 106 is located on the left side of the center line, the orientation of the red pixel opening is close to the spacer 106. If the spacer 106 is located on the right side of the center line, the orientation of the red pixel opening is away from the spacer 106. In the first display region AA1, the red pixel openings are arranged cyclically along the first direction, and at least two red pixel openings having different orientations are disposed in each cycle.

As shown in FIG. 4a, when the orientation of the red pixel opening is close to the spacer 106, the difference between the distance from the edge of the orthographic projection of the spacer 106 on the base substrate 101 to the edge of the orthographic projection of one of the two pixel openings 1051 adjacent to each other on the base substrate 101 and the distance from the edge of the orthographic projection of the spacer 106 on the base substrate 101 to the edge of the orthographic projection of the other of the two pixel openings 1051 on the base substrate 101 is smaller than the threshold value, which is, for example, 0.5 μm. When the difference is smaller than the threshold value, it indicates that a distance from the spacer 106 to one of the two pixel openings 1051 adjacent to each other along the first direction is substantially equal to a distance from the spacer 106 to the other of the two pixel openings 1051, that is, the spacer 106 is located in the middle of the two adjacent pixel openings 1051 along the first direction. For example, the distance from the edge of the orthographic projection of the spacer 106 on the base substrate 101 to the edge of the orthographic projection of one of the two pixel openings 1051 adjacent to each other along the first direction on the base substrate 101 and the distance from the edge of the orthographic projection of the spacer 106 on the base substrate 101 to the edge of the orthographic projection of the other of the two pixel openings 1051 on the base substrate 101 each are in a range of 13 μm±0.5 μm, which specifically may be 13.345 μm and 13.415 μm, respectively.

As shown in FIG. 4b, when the orientation of the red pixel opening is away from the spacer 106, which is different from the case in FIG. 4a because of the non-uniform red pixel opening, the difference between the distance from the edge of the orthographic projection of the spacer 106 on the base substrate 101 to the edge of the orthographic projection of one of the two pixel openings 1051 adjacent to each other on the base substrate 101 and the distance from the edge of the orthographic projection of the spacer 106 on the base substrate 101 to the edge of the orthographic projection of the other of the two pixel openings 1051 on the base substrate 101 is greater than the threshold value, which is, for example, 0.5 μm. When the difference is greater than the threshold value, it indicates that the distance from the spacer 106 to one of the two pixel openings 1051 adjacent to each other along the first direction is not equal to the distance from the spacer 106 to the other of the two pixel opening 1051, that is, the spacer 106 is not located in the middle of the two adjacent pixel openings 1051 along the first direction. For example, the distance from the spacer 106 to the one of the adjacent two pixel openings 1051 along the first direction is in a range of 13 μm±0.5 μm, which specifically may be 13.39 μm, and the distance from the spacer 106 to the other of the adjacent two pixel openings 1051 is in a range of 16 μm±0.5 μm, which specifically may be 16.125 μm.

As shown in FIG. 4a and FIG. 4b, a difference between a distance from the edge of the orthographic projection of the spacer 106 on the base substrate 101 to an edge of an orthographic projection of one of two pixel openings 1051 adjacent to each other along a second direction on the base substrate 101 and a distance from the edge of the orthographic projection of the spacer 106 on the base substrate 101 to an edge of an orthographic projection of the other of the two pixel openings 1051 on the base substrate 101 is smaller than the threshold value. The second direction intersects with the first direction.

The difference between the distance from the edge of the orthographic projection of the spacer 106 on the base substrate 101 to the edge of the orthographic projection of one of two pixel openings 1051 adjacent to each other along the second direction on the base substrate 101 and the distance from the edge of the orthographic projection of the spacer 106 on the base substrate 101 to the edge of the orthographic projection of the other of the two pixel openings 1051 on the base substrate 101 is smaller than a threshold value, which is, for example, 0.5 μm. When the difference is smaller than the threshold value, it indicates that a distance from the spacer 106 to one of the two pixel openings 1051 adjacent to each other along the second direction is substantially equal to a distance from the spacer 106 to the other of the two pixel openings 1051, that is, the spacer 106 is located in the middle of the two pixel openings 1051 adjacent to each other along the second direction. For example, the distance from the edge of the orthographic projection of the spacer 106 on the base substrate 101 to the edge of the orthographic projection of one of the two pixel openings 1051 adjacent to each other along the second direction on the base substrate 101 and the distance from the edge of the orthographic projection of the spacer 106 on the base substrate 101 to the edge of the orthographic projection of the other of the pixel openings 1051 on the base substrate 101 each are in a range of 14 μm±0.5 μm, which specifically may be 14.25 μm and 13.9 μm respectively, as shown in FIG. 4a; or specifically may be 14.295 μm and 13.93 μm respectively, as shown in FIG. 4b.

It is understood that the above threshold value may also be set to other smaller values according to actual needs, such as 0.3 μm, etc., and is not limited herein.

FIG. 5 is a schematic diagram showing a portion of the structure in the second display region of the display substrate in FIG. 1e. As shown in FIG. 5, in the second display region AA2, an orthographic projection of at least one spacer 106 on the base substrate 101 partially overlaps with an orthographic projection of at least one of the two adjacent connection vias V on the base substrate 101.

In the second display region AA2, a region between two adjacent pixel openings 1051 may be deemed as one-piece region, and the connection vias V for the first electrodes 1041 of every two light-emitting devices may be disposed in the same region, and thus (an area of) a region occupied by the connection vias V may be decreased, thereby facilitating the formation of the spacer 106 in the first display region AA1 and facilitating the formation of the first light-transmitting openings 1052 in the second display region AA2. In the second display region AA2, the spacer 106 may be disposed in the region corresponding to the two connection vias V to effectively support other film layers on the black pixel defining layer 105, and avoid a large difference between the display images in the second display region AA2 and the first display region AA1, thereby improving the display effect of the display substrate and improving the user's experience. The spacer 106 may cover one of the two connection vias V in the same region, so that the spacer 106 may collapse at a position of the one connection via V and therefore, the spacer 106 is stuck in the connection via V, and the spacer 106 is prevented from sliding relatively under the action of external force.

In some embodiments, the orthographic projection of the at least one spacer 106 on the base substrate 101 partially overlaps with an orthographic projection of each of the two adjacent connection vias V on the base substrate 101. The spacer 106 may cover the two connection vias V in the same region simultaneously, so that the space 106 may collapse at positions corresponding to the two connection vias V and therefore, the spacer 106 is stuck in the two connection vias V, and the spacer 106 is prevented from sliding relatively under the action of external force.

In some embodiments, as shown in FIG. 5, a distance from an edge of the orthographic projection of the at least one spacer 106 on the base substrate 101 to an edge of the orthographic projection of one of the two adjacent connection vias V on the base substrate 101 is equal to a distance from the opposite edge of the orthographic projection of the spacer 106 on the base substrate 101 to an edge of the orthographic projection of the other of the two adjacent connection vias V on the base substrate 101.

The spacer 106 may be located in the middle of the two connection vias V to ensure that the two ends of the spacer 106 have the same collapsing degree, thereby improving the supporting stability of the spacer 106. Meanwhile, when the spacer 106 collapses in the connection vias V, the spacer 106 may be fixed between the two connection vias V, so that the spacer is prevented from sliding under the action of stress to damage the structures in the pixel openings 1051, such as the light-emitting layers 1043 of the light-emitting devices.

Specifically, the distance from the edge of the orthographic projection of the at least one spacer 106 on the base substrate 101 to the edge of the orthographic projection of a corresponding one of the two adjacent connection vias V on the base substrate 101 is in a range from 0.2 μm to 0.5 μm.

An overlapping region where the spacer 106 overlaps with each of the two connection vias V may have a width in a range from from 0.2 μm to 0.5 μm, for example, 0.5 μm. That is, the spacer 106 may collapse in a region with a width of 0.5 μm. It should be noted that the width of the overlapping region cannot be too large or too small. If the width of the overlapping region is too large, the region where the spacer 106 collapses is easily too large, affecting the supporting effect of the spacer 106. If the width of the overlapping region is too small, the overlapping region cannot realize the stucking function, affecting the stability of the spacer 106.

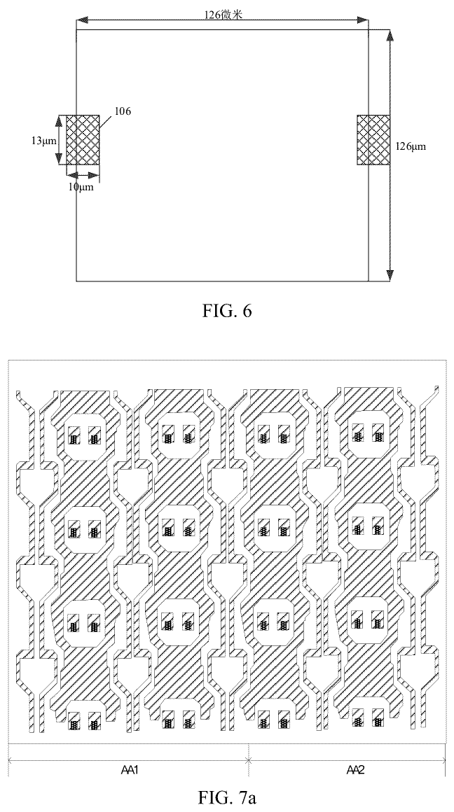

FIG. 6 is a schematic diagram showing a structure of the spacer in the display substrate shown in FIG. 1e. As shown in FIG. 6, the spacer 106 may be a pillar, a cross section of which along a horizontal direction may be rectangular. The spacer 106 may have a length in a range of 10 μm±0.5 μm along the first direction (i.e., the row direction) and a length in a range of 13 μm±0.5 μm along the second direction (i.e., the column direction). Specifically, the spacer 106 may have the length of 10 μm along the first direction and the length of 13 μm along the second direction, so that the spacer 106 may have a large bottom surface to ensure the supporting effect of the spacer.

In the display substrate, each pixel region generally has a size of 63 μm×63 μm. One spacer 106 may be disposed in every two pixel regions (126 μm×126 μm). The bottom surface of the spacer 106 may have an area of 10 μm×13 μm.. The arrangement density of the spacers 106 is (10×13)/(126×126)=0.8%. In practical applications, the arrangement density of the spacers 106 is greater than or equal to 0.8%, so that other film layers on the black pixel defining layer 105 can be effectively supported, thereby avoiding a large difference between the display pictures in the second display region AA2 and the first display region AA1, improving the display effect of the display substrate, and improving the user's experience.

In some embodiments, as shown in FIG. 2 and FIG. 3, the display substrate further includes: an encapsulation layer 107 and a black matrix layer 108 that are sequentially arranged on a side of the light-emitting device layer 104 away from the base substrate 101. The black matrix layer 108 has a second light-transmitting opening 1081. An orthographic projection of the second light-transmitting opening 1081 on the base substrate 101 at least partially overlaps with the orthographic projection of the pixel opening 1051 on the base substrate 101.

The encapsulation layer 107 may include a plurality of encapsulation sub-layers to improve encapsulation effect. For example, the encapsulation layer 107 may be a composite encapsulation layer including a first inorganic encapsulation layer, an organic encapsulation layer, and a second inorganic encapsulation layer. For example, each of the first inorganic encapsulation layer and the second inorganic encapsulation layer may be made of an inorganic material, such as silicon nitride, silicon oxide, or silicon oxynitride, and the organic encapsulation layer may be made of an organic material, such as Polyimide (PI) or epoxy. The composite encapsulation layer may avoid the damage to the light-emitting device due to the invasion of gases such as water, oxygen and the like, so as to provide multiple protections for the light-emitting device layer in the display substrate, and realize a better encapsulation effect.

The black matrix layer 108 may be formed on the encapsulation layer 107. The black matrix layer 108 may absorb the ambient light, so as to prevent the ambient light from irradiating on the light-emitting device layer 104 and being reflected by the first electrode 1041 of the light-emitting device layer 104, so as to reduce the light reflectivity of the display substrate, and improve the display effect of the display substrate. The black matrix layer 108 is formed with a second light-transmitting opening 1081 therein. The second light-transmitting opening 1081 may be disposed corresponding to the pixel opening 1051 of the black pixel defining layer 105, and may transmit light emitted by the light-emitting device in the pixel opening 1051, so as to realize the display function.

In some embodiments, as shown in FIG. 2, an area of the orthographic projection of the second light-transmitting opening 1081 on the base substrate 101 is larger than an area of the orthographic projection of the pixel opening 1051 on the base substrate 101.

The area of the second light-transmitting opening 1081 may be slightly larger than that of the pixel opening 1051, so that the second light-transmitting opening 1081 may completely transmit the light emitted from the light-emitting device in the pixel opening 1051 and prevent the ambient light from being irradiated onto the first electrode 1041 and reflected by the first electrode 1041. Specifically, the second light-transmitting opening 1081 directly faces the pixel opening 1051, and the orthographic projection of the pixel opening 1051 on the base substrate 101 is within the orthographic projection of the second light-transmitting opening 1081 on the base substrate 101.

In some embodiments, a distance from the edge of the orthographic projection of the spacer 106 on the base substrate 101 to an edge of an orthographic projection of the black matrix layer 108 on the base substrate 101 is greater than or equal to 1.58 μm.

The edge of the spacer 106 is spaced apart from the edge of the black matrix layer 108 by a certain distance, so as to prevent the black matrix layer 108 from blocking light emitted by the light-emitting device in the pixel opening 1051 and affecting the display effect. Specifically, the distance from the edge of the spacer 106 to the edge of the black matrix layer 108 may be greater than or equal to 1.58 μm, for example, the distance being 1.58 μm.

In some embodiments, as shown in FIG. 2, the display substrate further includes: a color filter layer 109. The color filter layer 109 includes: a plurality of color filters 1091, and each of the color filters 1091 covers a corresponding second light-transmitting opening 1081.

The second light-transmitting opening 1081 in the black matrix layer 108 may transmit a part of the ambient light to the first electrode 1041 of the light-emitting device, the first electrode 1041 may reflect the part of ambient light, the reflected light may pass through the color filter 1091 of the color filter layer 109, so that the ambient light may be filtered to obtain light of a corresponding color. For example, a color of the color filter 1091 is the same as a color of the light-emitting device in the pixel opening 1051 corresponding to the color filter 1091. Therefore, the ambient light may be filtered to obtain the light required for displaying, so that the utilization rate of the light and the display brightness of the display substrate can be improved.

In some embodiments, the black matrix layer 108 further has a third light-transmitting opening (not shown) between adjacent ones of a part of the second light-transmitting openings 1081. An orthographic projection of the third light-transmitting opening on the base substrate 101 at least partially overlaps with the orthographic projection of the first light-transmitting opening 1052 on the base substrate 101.

The third light-transmitting opening in the black matrix layer 108 may directly face the first light-transmitting opening 1052 in the black pixel defining layer, so as to prevent the black matrix layer 108 from shielding the light transmitted through the first light-transmitting opening 1052 to affect the effect of light sensing. Specifically, an area of the orthographic projection of the third light-transmitting opening on the base substrate 101 is larger than that of the orthographic projection of the first light-transmitting opening 1052 on the base substrate 101. The orthographic projection of the first light-transmitting opening 1052 on the base substrate 101 falls within the orthographic projection of the third light-transmitting opening on the base substrate 101.

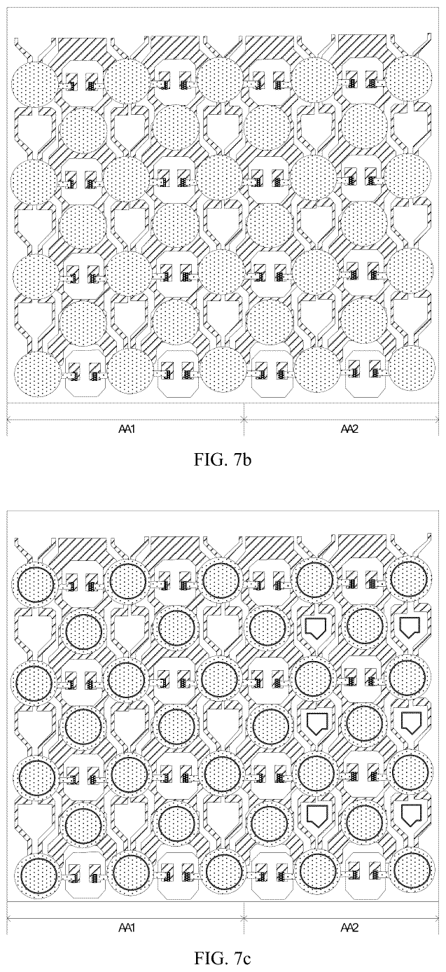

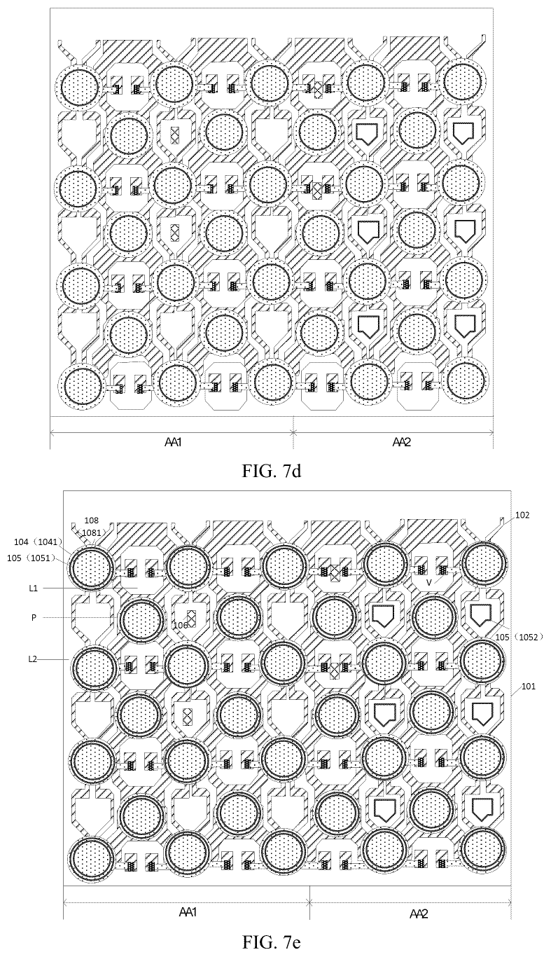

FIG. 7a to FIG. 7e are schematic diagrams showing structures of layers of a display substrate according to another embodiment of the present disclosure. As shown in FIG. 1e and FIG. 7e, the driving circuit layer 102 has a plurality of first hollow portions L1. An orthographic projection of each first hollow portion L1 on the base substrate 101 at least partially overlaps with the orthographic projection of the connection via V on the base substrate 101.

Each of the plurality of first hollow portions L1 may correspond to two connection vias V. The first electrodes 1041 of two different light-emitting devices are connected respectively to different signal lines, so as to avoid short circuit between the two different first electrodes 1041 to influence the display effect.

In some embodiments, as shown in FIG. 1e, the driving circuit layer 102 further includes a flat portion P between the adjacent first hollow portions L1. An orthographic projection of the flat portion P on the base substrate 101 at least partially overlaps with the orthographic projection of the pixel opening 1051 on the base substrate 101.

The pixel opening 1051 may be disposed correspondingly to the flat portion P. A signal line in the driving circuit layer 102 may pass through a position corresponding to the flat portion P, so that the signal line is electrically connected to the first electrode 1041 of the light-emitting device.

In some embodiments, as shown in FIG. 7e, the driving circuit layer 102 further includes a second hollow portion L2. An orthographic projection of the second hollow portion L2 on the base substrate 101 at least partially overlaps with the orthographic projection of the pixel opening 1051 on the base substrate 101.

The pixel opening 1051 may disposed correspondingly to the second hollow portion L2. The signal line in the driving circuit layer 102 may pass through a position corresponding to the second hollow portion L2, so that the signal line is electrically connected to the first electrode 1041 of the light-emitting device.

In a second aspect, an embodiment of the present disclosure provides a display device including the display substrate provided in any one of the above embodiments. The display device may be any product or component with a display function, such as a television, a mobile phone, a display, a notebook computer, a digital photo frame, or a navigator or the like. The implementation principle for the display device is similar to that of the display substrate, and is not described herein again.

It will be understood that the above embodiments are merely exemplary embodiments for illustrating the principles of the present disclosure, and the present disclosure is not limited thereto. It will be apparent to those skilled in the art that various changes and modifications can be made therein without departing from the spirit and essence of the present disclosure, and these changes and modifications are to be considered within the scope of the present disclosure.

1. A display substrate having a first display region and a second display region, wherein the display substrate comprises: a base substrate, a driving circuit layer, at least one planarization layer, and a light-emitting device layer sequentially arranged on the base substrate; the light-emitting device layer comprises: a plurality of light-emitting devices each comprising: a first electrode electrically connected to the driving circuit layer through a connection via penetrating through the at least one planarization layer; the display substrate further comprises: a black pixel defining layer on a side of the at least one planarization layer away from the base substrate, and a spacer on a side of the black pixel defining layer away from the base substrate;
in the first display region, the black pixel defining layer comprises a plurality of pixel openings each exposing the first electrode; an orthographic projection of the spacer on the base substrate does not overlap with orthographic projections of the plurality of pixel openings and the connection via on the base substrate, and
in the second display region, the black pixel defining layer further comprises a first light-transmitting opening between adjacent ones of a part of pixel openings; the orthographic projection of the spacer on the base substrate does not overlap with orthographic projections of the plurality of pixel openings and the first light-transmitting opening on the base substrate, and at least partially overlaps with the orthographic projection of the connection via on the base substrate.

2. The display substrate of claim 1, wherein in the first display region, a part of the pixel openings have an irregular shape and have orientations arranged cyclically along a first direction, and at least two pixel openings with different orientations are disposed in each cycle;
the orientation of the pixel opening is close to the spacer, and a difference between a distance from an edge of the orthographic projection of the spacer on the base substrate to an edge of an orthographic projection of one of two pixel openings adjacent to each other along the first direction on the base substrate and a distance from the edge of the orthographic projection of the spacer on the base substrate to an edge of an orthographic projection of the other of the two pixel openings on the base substrate is smaller than a threshold value, and
the orientation of the pixel opening is away from the spacer, and the difference between the distance from the edge of the orthographic projection of the spacer on the base substrate to the edge of the orthographic projection of the one of the two pixel openings adjacent to each other along the first direction on the base substrate and the distance from the edge of the orthographic projection of the spacer on the base substrate to the edge of the orthographic projection of the other of the two pixel openings on the base substrate is greater than the threshold value.

3. The display substrate of claim 2, wherein
the orientation of the pixel opening is close to the spacer, and the distance from the edge of the orthographic projection of the spacer on the base substrate to the edge of the orthographic projection of the one of the two pixel openings adjacent to each other along the first direction on the base substrate and the distance from the edge of the orthographic projection of the spacer on the base substrate to the edge of the orthographic projection of the other of the two pixel openings on the base substrate are each in a range of 13 μm±0.5 μm, and
the orientation of the pixel openings is away from the spacer, the distance from the edge of the orthographic projection of the spacer on the base substrate to the edge of the orthographic projection of the one of the two pixel openings adjacent to each other along the first direction on the base substrate is in a range of 13 μm±0.5 μm, and the distance from the edge of the orthographic projection of the spacer on the base substrate to the edge of the orthographic projection of the other of the two pixel openings on the base substrate is in a range of 16 μm±0.5 μm.

4. The display substrate of claim 3, wherein a difference between a distance from an edge of the orthographic projection of the spacer on the base substrate to an edge of an orthographic projection of one of two pixel openings adjacent to each other along a second direction on the base substrate and a distance from the edge of the orthographic projection of the spacer on the base substrate to an edge of an orthographic projection of the other of the two pixel openings on the base substrate is smaller than a threshold value, and the second direction intersects with the first direction.

5. The display substrate of claim 4, wherein the distance from the edge of the orthographic projection of the spacer on the base substrate to the edge of the orthographic projection of the one of the two pixel openings adjacent to each other along the second direction on the base substrate and the distance from the edge of the orthographic projection of the spacer on the base substrate to the edge of the orthographic projection of the other of the pixel openings on the base substrate are each in a range of 14 μm±0.5 μm.

6. The display substrate of claim 1, wherein in the second display region, an orthographic projection of at least one spacer on the base substrate partially overlaps with an orthographic projection of at least one of two adjacent connection vias on the base substrate.

7. The display substrate of claim 6, wherein the orthographic projection of the at least one spacer on the base substrate partially overlaps with orthographic projections of the two adjacent connection vias on the base substrate, respectively.

8. The display substrate of claim 7, wherein a distance from an edge of the orthographic projection of the at least one spacer on the base substrate to an edge of an orthographic projection of one of the two adjacent connection vias on the base substrate is equal to a distance from an opposite edge of the orthographic projection of the spacer on the base substrate to an edge of an orthographic projection of the other of the two adjacent connection vias on the base substrate.,
wherein the distance from the edge of the orthographic projection of the at least one spacer on the base substrate to the edge of the orthographic projection of the one of the two adjacent connection vias on the base substrate and the distance from the opposite edge of the orthographic projection of the spacer on the base substrate to the edge of the orthographic projection of the other of the two adjacent connection vias on the base substrate are each in a range from 0.2 μm to 0.5 μm.

9. (canceled)

10. The display substrate of claim 1, wherein the spacer has a length in a range of 10 μm±0.5 μm along a first direction and a length in a range of 13 μm±0.5 μm along a second direction, with the second direction intersecting with the first direction.

11. The display substrate of claim 10, comprising a plurality of spacers, and an arrangement density of the plurality of spacer is greater than or equal to 0.8%.

12. The display substrate of claim 1, further comprising: an encapsulation layer and a black matrix layer sequentially arranged on a side of the light-emitting device layer away from the base substrate, wherein
the black matrix layer comprises a second light-transmitting opening, and an orthographic projection of the second light-transmitting opening on the base substrate at least partially overlaps with an orthographic projection of the corresponding pixel opening on the base substrate.

13. The display substrate of claim 12, wherein an area of the orthographic projection of the second light-transmitting opening on the base substrate is larger than an area of the orthographic projection of the corresponding pixel opening on the base substrate,
the orthographic projection of each pixel opening on the base substrate is within the orthographic projection of the corresponding second light-transmitting opening on the base substrate.

14. (canceled)

15. The display substrate of claim 12, wherein a distance from an edge of the orthographic projection of the spacer on the base substrate to an edge of an orthographic projection of the black matrix layer on the base substrate is greater than or equal to 1.58 μm.

16. The display substrate of claim 12, further comprising a color filter layer comprising a plurality of color filters, wherein
each of the plurality of color filters covers the second light-transmitting opening-,
each color filter has the same color as a color of a light-emitting device in the corresponding pixel opening.

17. (canceled)

18. The display substrate of claim 12, wherein the black matrix layer further comprises a third light-transmitting opening between adjacent ones of a part of the second light-transmitting openings; and
an orthographic projection of the third light-transmitting opening on the base substrate at least partially overlaps with the orthographic projection of the first light-transmitting opening on the base substrate.

19. The display substrate of claim 18, wherein an area of the orthographic projection of the third light-transmitting opening on the base substrate is larger than an area of the orthographic projection of the first light-transmitting opening on the base substrate.,
the orthographic projection of the first light-transmitting opening on the base substrate is within the orthographic projection of the third light-transmitting opening on the base substrate.

20. (canceled)

21. The display substrate of claim 1, wherein the driving circuit layer comprises a plurality of first hollow portions, and an orthographic projection of each first hollow portion on the base substrate at least partially overlaps with the orthographic projection of the corresponding connection via on the base substrate.

22. The display substrate of claim 21, wherein the driving circuit layer further comprises a flat portion between the adjacent first hollow portions, and an orthographic projection of the flat portion on the base substrate at least partially overlaps with the orthographic projection of the corresponding pixel opening on the base substrate.

23. The display substrate of claim 21, wherein the driving circuit layer further comprises a second hollow portion, and an orthographic projection of the second hollow portion on the base substrate at least partially overlaps with the orthographic projection of the corresponding pixel opening on the base substrate.

24. A display device, comprising the display substrate of claim 1.
